(19) United States
(12) Patent Application Publication
(10) Pub. No.: US 2019/0316671 A1
(43) Pub. Date: Oct. 17, 2019

(54) COVER FIXING STRUCTURE AND MOTOR

(71) Applicant: NIDEC SANKYO CORPORATION, NAGANO (JP)

(72) Inventors: Kazumi FURUBAYASHI, NAGANO (JP); Takashi HIGUCHI, NAGANO (JP)

(73) Assignee: NIDEC SANKYO CORPORATION, NAGANO (JP)

(21) Appl. No.: 16/343,410

(22) PCT Filed: Oct. 3, 2017
(86) PCT No.: PCT/JP2017/035894

§ 371 Date: Apr. 19, 2019

(30) Foreign Application Priority Data
Oct. 21, 2016 (JP) 2016-206873

(51) Int. Cl. F16H 57/031; H05K 5/03; H02K 5/04; H02K 7/116

(52) U.S. Cl. CPC F16H 57/031; H02K 7/116; H02K 5/04; H05K 5/03

(57) ABSTRACT

The motor (1) is provided with a frame (3) (support member) that includes a third plate (33) (first support unit) supporting a gear cover (7) on one side (X1) in a first direction (X), and a first plate (31) (second support unit) supporting the gear cover on one side (Z1) in a second direction (Z). The gear cover includes a flexible plate (735) (biasing force generation unit) configured to generate a biasing force for biasing the gear cover in an inclined direction inclined toward both the other side (X2) in the first direction and the one side in the second direction, upon pressing the gear cover against the third plate. The first plate includes surface (318) (first abutment unit) abutting against the gear cover, and a hole (311) provided with an inner peripheral surface (second abutment unit) abutting against the convex portion (741) of the gear cover.

### TECHNICAL FIELD

The present invention relates to a cover fixing structure and a motor in which a gear transmission mechanism is covered with a gear cover.

### BACKGROUND ART

In a motor (geared motor) in which rotation of a motor shaft of a motor main body is transmitted to a rotation shaft via a gear transmission mechanism, a structure is adopted where a frame is provided at an end on an output side of the motor main body and between a first plate and a second plate of the frame, a rotation shaft is rotatably arranged (see Patent Literature 1).

### CITATION LIST

### Patent Literature

[Patent Literature 1] Japanese Unexamined Patent Application Publication No. 2009-124868

### SUMMARY

### Problems to be Solved by the Invention

In the motor described in Patent Literature 1, there is a problem that, for example, a foreign matter adheres to the gear transmission mechanism, and to avoid this, it is preferable to cover the gear transmission mechanism with a gear cover. In that case, the gear cover will be fixed by an engagement mechanism such as a hook by utilizing a third plate configured to couple the first plate and the second plate, and the first plate in the frame; however, if a clearance in the engagement mechanism is large, the rotation shaft rattles to produce unusual sound when the rotation shaft rotates. However, if the clearance in the engagement mechanism is made small, it is necessary to deform the engagement mechanism such as a hook with a large force, and the workability for fixing the cover is deteriorated. Such a problem is generated not only in a case where the gear cover is fixed to the frame, but is generated also in a case where the cover is fixed to a support member.

In view of the above problems, an object of the present invention is to provide a cover fixing structure capable of easily fixing a cover to a support member while suppressing rattling, and to provide a motor therefor.

### Means for Solving the Problem

To solve the above problems, the present invention provides a cover fixing structure for fixing a cover to a support member, wherein the support member includes a first support unit configured to support the cover on one side in a first direction, and a second support unit configured to support the cover at one side in a second direction orthogonal to the first direction, one of the cover and the support member includes a biasing force generation unit configured to generate, in a case that the cover is pressed against the first support unit, a biasing force for biasing the cover in an inclined direction inclined toward both the other side of the first direction and the one side of the second direction, and the second support unit includes a first abutment unit configured to abut the cover from the one side in the second direction, and a second abutment unit configured to abut the cover from the other side in the first direction.

In the present invention, the support member includes the first support unit configured to support the cover on one side in the first direction, and the second support unit configured to support the cover on one side in the second direction. When the cover is pressed against the first support unit of the support member, the biasing force generation unit biases the cover in an inclined direction inclined toward both the other side in the first direction and the one side in the second direction. As a result, the cover elastically abuts the second support unit with elasticity relative to the second support unit, and the second abutment unit provided at the second support unit elastically abuts the cover from the other side in the first direction. Therefore, the cover can be fixed to the first support unit and the second support unit with a simple operation of pressing the cover against the first support unit of the support member. In addition, since the cover is elastically fixed to the first support unit and the second support unit, rattling hardly occurs.

The present invention may adopt an aspect where the biasing force generation unit is a flexible plate configured to warp while an inclined surface inclined toward both the first direction and the second direction being a contact surface between the cover and the first support unit when the cover is pressed against the first support unit, to generate the biasing force. According to this aspect, it is possible to configure a biasing force generation unit configured to generate a biasing force in a predetermined direction by the flexible plate.

The present invention may adopt an aspect where the flexible plate is formed in the cover to extend in the second direction with a free end thereof facing the other side in the second direction, the flexible plate is formed with the inclined surface formed to face an inclined direction inclined toward both the one side in the first direction and the other side in the second direction, and the flexible plate warps toward the other side in the first direction when the cover is pressed against the first support unit to generate the biasing force. According to such an aspect, since the biasing force generation unit can be configured by the flexible plate provided in the cover, it is unnecessary to add another member to configure the biasing force generation unit.

The present invention may adopt an aspect where the inclined surface is formed in a convex portion protruding from the flexible plate toward the one side in the first direction, the first support unit is provided with an opening portion opening toward the other side in the first direction, the convex portion fitting into the opening portion when the cover is pressed against the first support unit, and an opening edge on the other side in the first direction of the opening portion abuts the inclined surface. According to this aspect, generation of a large gap between the first support unit and the cover can be avoided.

The present invention may adopt an aspect where the second abutment unit is formed of an inner peripheral surface of a hole into which the convex portion formed on the cover is fitted, the hole being provided in the second support unit, and an outer peripheral surface of a convex portion fitted into the hole formed on the cover, the convex portion being formed in the second support unit. According to such an aspect, the second abutment unit can be configured with a simple configuration.

The present invention may adopt an aspect where the cover includes a hook protruding toward the other side in the second direction and elastically engaging with the second support unit. According to such a configuration, even if a large force is applied to the cover, it is possible to prevent the cover from coming off to the other side in the second direction, and further, since the cover is fixed by the biasing force generation unit, the first abutment unit, and the second abutment unit, and thus, even if a clearance between the hook and the second support unit is large, rattling hardly occurs. Therefore, since a large force is not required for engaging the hook, assembling work can be performed efficiently.

The present invention may adopt an aspect where an engagement unit configured to position a third direction orthogonal to both the first direction and the second direction of the cover is configured by a convex portion formed in one of the first support unit and the cover and a concave portion formed in the other one of the first support unit and the cover, where the convex portion is fitted into the concave portion. According to such an aspect, it is possible to surely position the cover in the third direction.

The cover fixing structure according to the present invention can be applied to, for example, a motor. In this case, the motor includes a motor main body having a motor axis extending along the second direction, a frame including a first plate fixed to an end on the other side in the second direction of the motor main body, a second plate facing the first plate on the other side in the second direction, and a third plate configured to couple the first plate and the second plate at one side in the first direction, a rotation shaft arranged between the first plate and the second plate, a gear transmission mechanism configured to transmit rotation of the motor shaft of the motor main body to a gear unit of the rotation shaft, and a gear cover fixed to the frame to cover the gear transmission mechanism between the first plate and the second plate, wherein the frame is the support member, the gear cover is the cover, the third plate is the first support unit, and the first plate is the second support unit. According to such an aspect, rattling hardly occurs between the frame and the gear cover, so that occurrence of abnormal noise and the like can be suppressed even if vibration occurs due to the rotation of the motor.

### Effect of the Invention

In the present invention, the support member includes the first support unit configured to support the cover on one side in the first direction, and the second support unit configured to support the cover on one side in the second direction. When the cover is pressed against the first support unit of the support member, the biasing force generation unit biases the cover in an inclined direction inclined toward both the other side in the first direction and the one side in the second direction. As a result, the cover elastically abuts the second support unit with elasticity relative to the second support unit, and the second abutment unit provided at the second support unit elastically abuts the cover from the other side in the first direction. Therefore, the cover can be fixed to the first support unit and the second support unit with a simple operation of pressing the cover against the first support unit of the support member. In addition, since the cover is elastically fixed to the first support unit and the second support unit, rattling hardly occurs.

### BRIEF DESCRIPTION OF THE DRAWINGS

FIG. 1 is an explanatory view of a motor to which the present invention is applied as seen from a side of a rotation shaft.

FIG. 2 is an exploded perspective view of a state where a gear cover is removed from the state illustrated in FIG. 1.

FIG. 3 is a perspective view illustrating a state where the gear cover is fixed to a frame in the motor illustrated in FIG. 1, as seen from a side of a first plate of the frame.

FIG. 4 is an exploded perspective view of a state where the gear cover is removed from the state illustrated in FIG. 3.

FIG. 5 is an X-Z sectional view illustrating a state where the gear cover and the like are cut at a position passing through a flexible plate of the gear cover in the state illustrated in FIG. 3.

FIG. 6 is a cross-sectional view of a state where the gear cover is removed from the state illustrated in FIG. 5.

FIG. 7 is a Y-Z sectional view illustrating a state where the gear cover and the like are cut at a position passing through a convex portion of the gear cover in the state illustrated in FIG. 3.

### DESCRIPTION OF THE EMBODIMENTS

With reference to the drawings, a cover fixing structure to which the present invention is applied will be described. In the following description, as a structure for fixing a cover to a support member, a case where a gear cover 7 (cover) is fixed to a frame 3 (support member) of a motor 1 will be mainly described.

It is noted that in the motor 1 described below, a rotation center axis of a motor shaft 50 of a motor main body 10 and a rotation center axis of a rotation shaft 8 are parallel, both of which can be regarded as a motor axis. In the following description, the rotation center axis of the rotation shaft 8 will be described as a motor axis L. Further, in the following description, out of directions in which the motor axis L extends (motor axis L directions), one side where the motor shaft 50 protrudes from the motor main body 10 is set as an output side L1 and a side (the other side) opposing to the side where the motor shaft 50 protrudes from the motor main body 10 is defined as an opposite output side L2.

Further, out of directions orthogonal to the motor axis L, in the frame 3, a direction orthogonal to a third plate 33 is defined as a first direction X, a direction in which the motor axis L extends is defined as a second direction Z, and a direction orthogonal to the first direction X and the second direction Z is defined as a third direction Y. Further, in the first direction X, a side on which the third plate 33 is located in the frame 3 is defined as one side X1 and a side where a first plate 31 and a second plate 32 protrude from the third plate 33 is defined as the other side X2. Further, in the second direction Z, the opposite output side L2 is defined as one side Z1 and the output side L1 is defined as the other side Z2. Further, the following description proceeds where Y1 is allotted to one side in the third direction Y and Y2 is allotted to the other side thereof.

### Overall Configuration

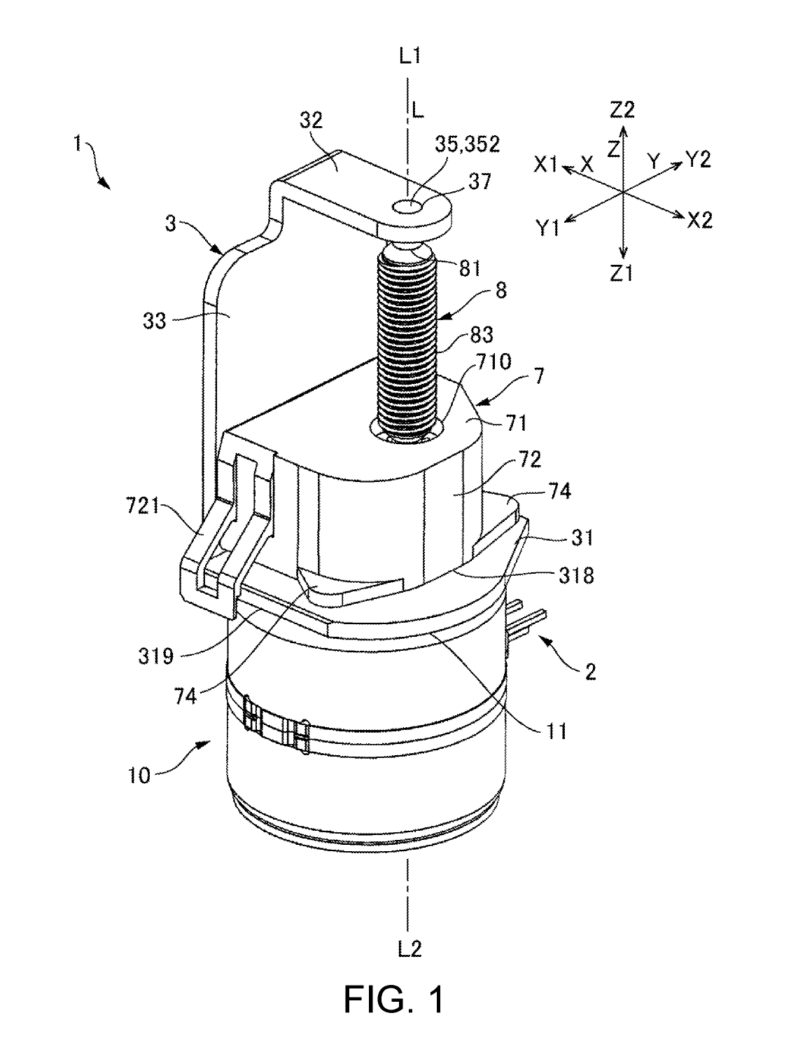

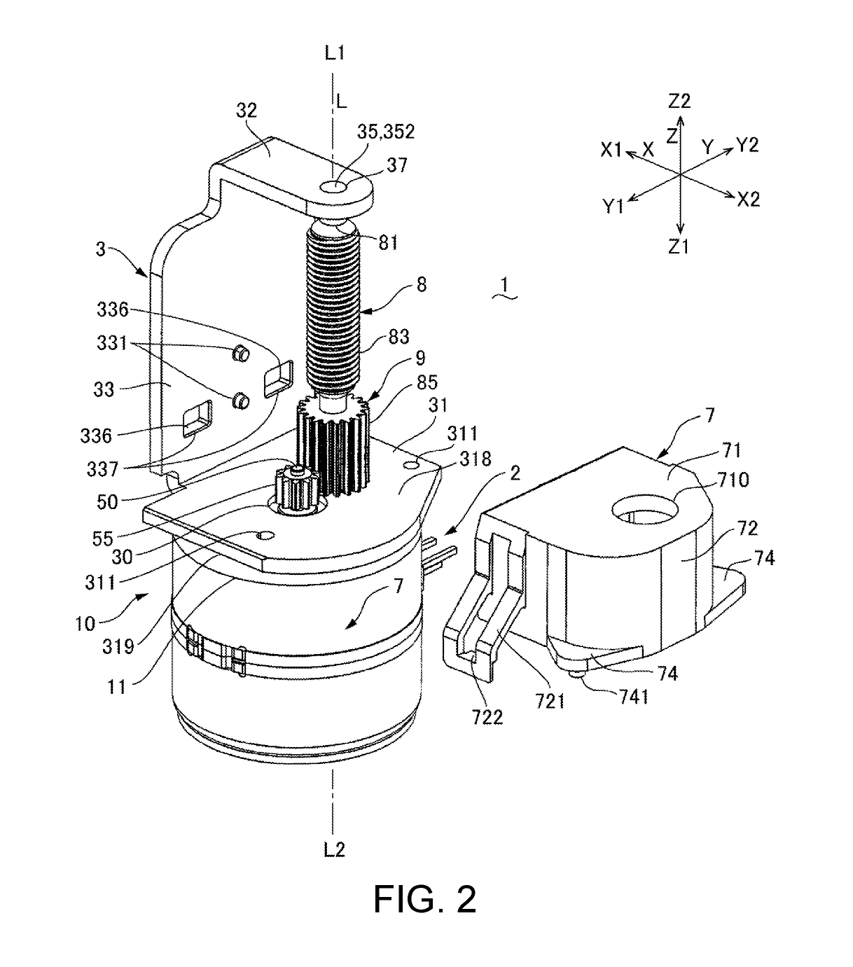

FIG. 1 is an explanatory view of the motor 1 to which the present invention is applied as seen from a side of the rotation shaft 8. FIG. 2 is an exploded perspective view of a state where the gear cover 7 is removed from the state illustrated in FIG. 1.

As illustrated in FIG. 1 and FIG. 2, the motor 1 includes the motor main body 10 and the frame 3 fixed to an end 11 on one side (output side L1) in the motor axis L direction of the motor main body 10. The frame 3 includes the first plate 31 fixed to the end 11 on the output side L1 of the motor main body 10 by welding and the like, the second plate 32 facing the first plate 31 at the output side L1, and the third plate 33 configured to couple the first plate 31 and the second plate 32 on the one side X1 in the first direction X. Therefore, the first plate 31 and the second plate 32 are structured to be bent from the third plate 33 toward the other side X2 in the first direction X. A power feeding unit 2 is provided on a side surface of the motor main body 10. A hole 30 is formed in the first plate 31, and the motor shaft 50 of the motor main body 10 protrudes from the first plate 31 toward the output side L1 through the hole 30. In the motor shaft 50, a motor pinion 55 is fixed to a portion protruding from the first plate 31 toward the output side L1.

A gear transmission mechanism 9 is provided between the first plate 31 and the second plate 32, and rotation of the motor pinion 55 (rotation of the motor shaft 50) is transmitted via the gear transmission mechanism 9 to the rotation shaft 8. The gear cover 7 configured to cover the gear transmission mechanism 9 at the output side L1 is arranged between the first plate 31 and the second plate 32, and the gear cover 7 is fixed to the frame 3.

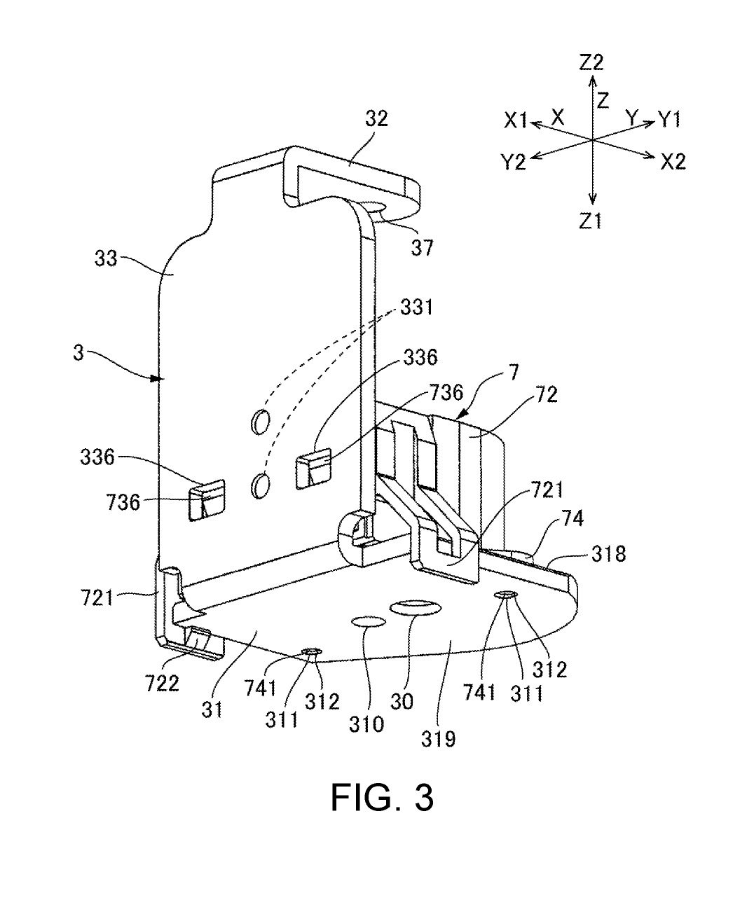

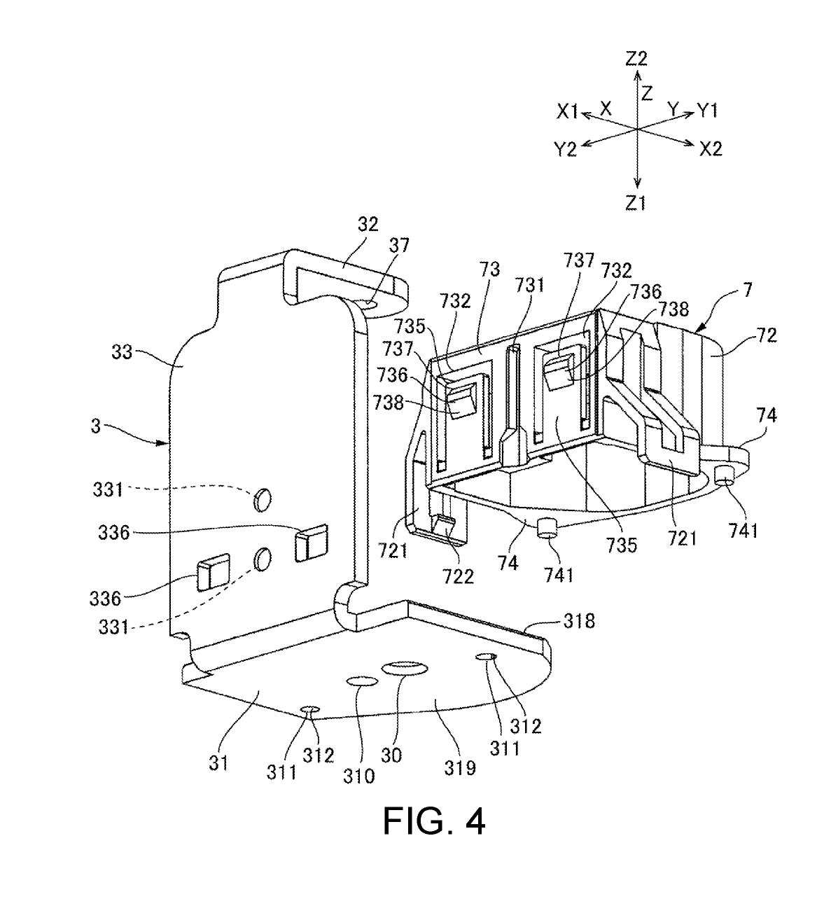

A fixation shaft 35 is provided between the first plate 31 and the second plate 32, and the fixation shaft 35 rotatably supports the rotation shaft 8 around the motor axis L. In the fixation shaft 35, a shaft end (not illustrated) on the opposite output side L2 is held in a fixation shaft supporting hole 310 (see FIG. 3 and FIG. 4) formed in the first plate 31. A shaft end 352 of the fixation shaft 35 on the output side L1 is fixed to the second plate 32 while being fitted in a through hole 37 formed in the second plate 32. For such fixation, methods such as welding, caulking, and adhesion can be adopted.

### Configuration of Rotation Shaft 8 and Gear Transmission Mechanism 9

The rotation shaft 8 is a shaft shaped member formed with a shaft hole 81 through which the fixation shaft 35 passes, and a gear 85 and a spiral groove 83 are formed in this order from the opposite output side L2 toward the output side L1 on the circumference of the rotation shaft 8. In the present embodiment, the rotation shaft 8 is configured as a feed screw or a worm by the spiral groove 83. The rotation shaft 8 is made of resin, and the gear 85 and the spiral groove 83 are integrally formed.

In the rotation shaft 8, the gear 85 meshes with the motor pinion 55 to configure the gear transmission mechanism 9. Here, an outer diameter of the gear 85 is larger than an outer diameter of the motor pinion 55. Therefore, the rotation of the motor shaft 50 is transmitted, while being decelerated, to the rotation shaft 8 through the gear transmission mechanism 9 (the motor pinion 55 and the gear 85).

### Configuration of Gear Cover 7

FIG. 3 is a perspective view illustrating a state where the gear cover 7 is fixed to the frame 3 in the motor 1 illustrated in FIG. 1, as seen from a side of the first plate 31 of the frame 3. FIG. 4 is an exploded perspective view of a state where the gear cover 7 is removed from the state illustrated in FIG. 3.

As illustrated in FIG. 1, FIG. 2, FIG. 3, and FIG. 4, the gear cover 7 includes an end plate 71 configured to cover the gear transmission mechanism 9 at the output side L1, and a first side plate 72 configured to surround the gear transmission mechanism 9 from the other side X2 in the first direction X and the both sides in the third direction Y. The end plate 71 is provided with a through hole 710 through which a portion where the spiral groove 83 is formed on the rotation shaft 8 is passed out toward a side of the first plate 31 (output side L1).

The gear cover 7 further includes a second side plate 73 configured to cover the gear transmission mechanism 9 from the one side X1 in the first direction X, and two flanges 74 protruding to both sides in the third direction Y from a portion located opposite to the third plate 33, out of the end of the one side Z1 in the second direction Z of the first side plate 72. The third plate 33 of the frame 3 abuts against the second side plate 73 of the gear cover 7 to support the gear cover 7 on the one side X1 in the first direction X. A surface 318 on the other side Z2 in the second direction Z of the first plate 31 of the frame 3 abuts against an end on the one side Z1 in the second direction Z of the first side plate 72 including the flanges 74 of the gear cover 7 to support the gear cover 7 on the one side Z1 in the second direction Z.

### Detailed Configuration of Gear Cover 7 and Frame 3

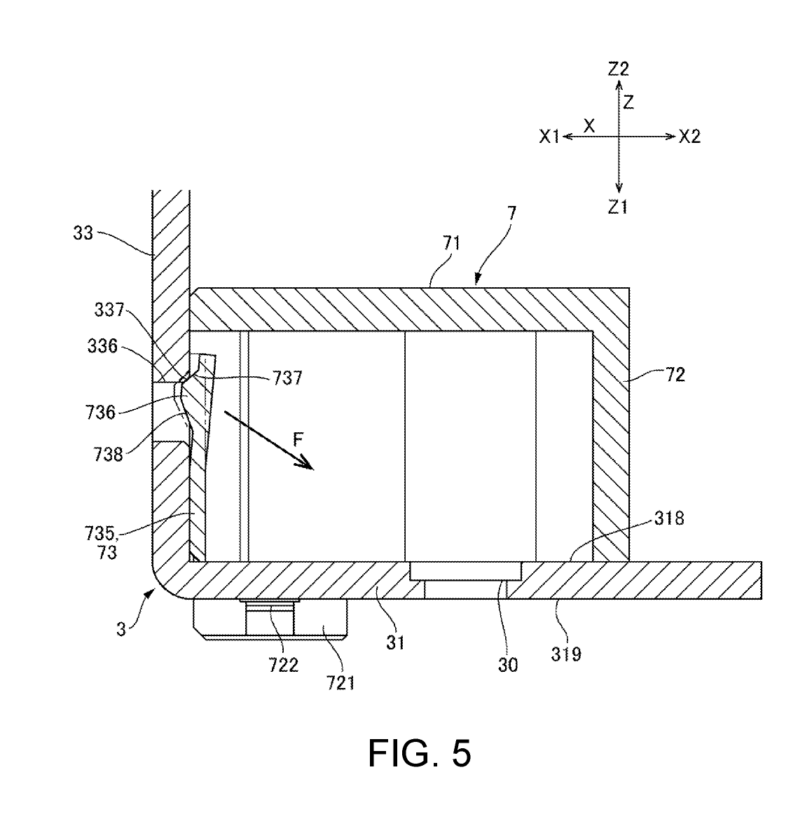

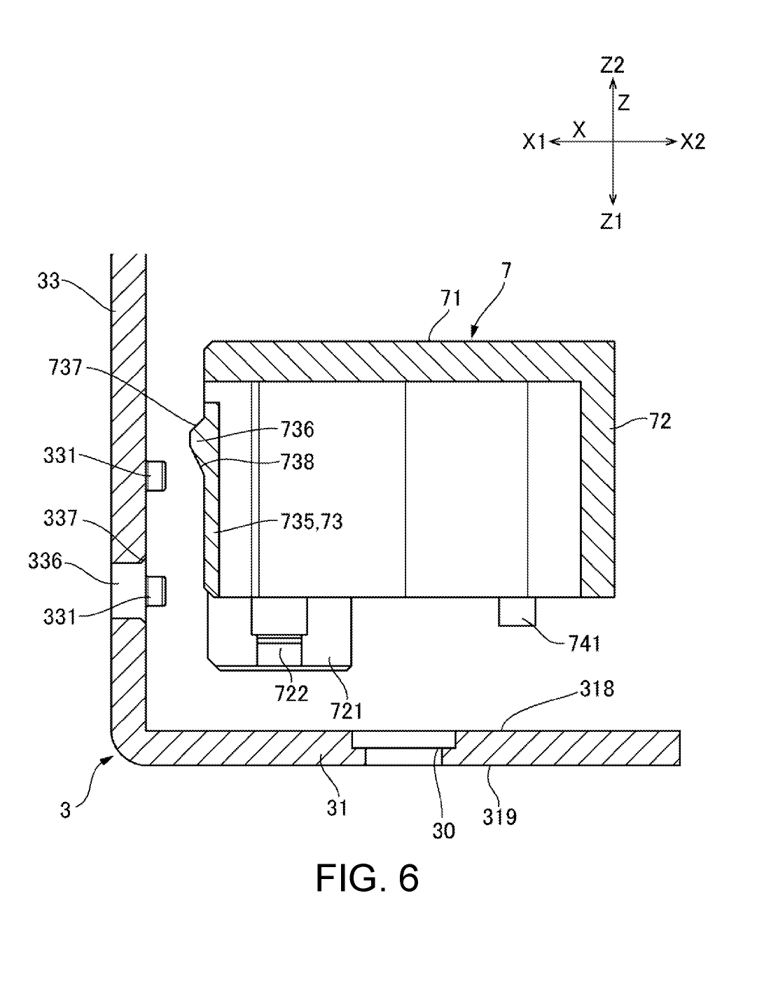

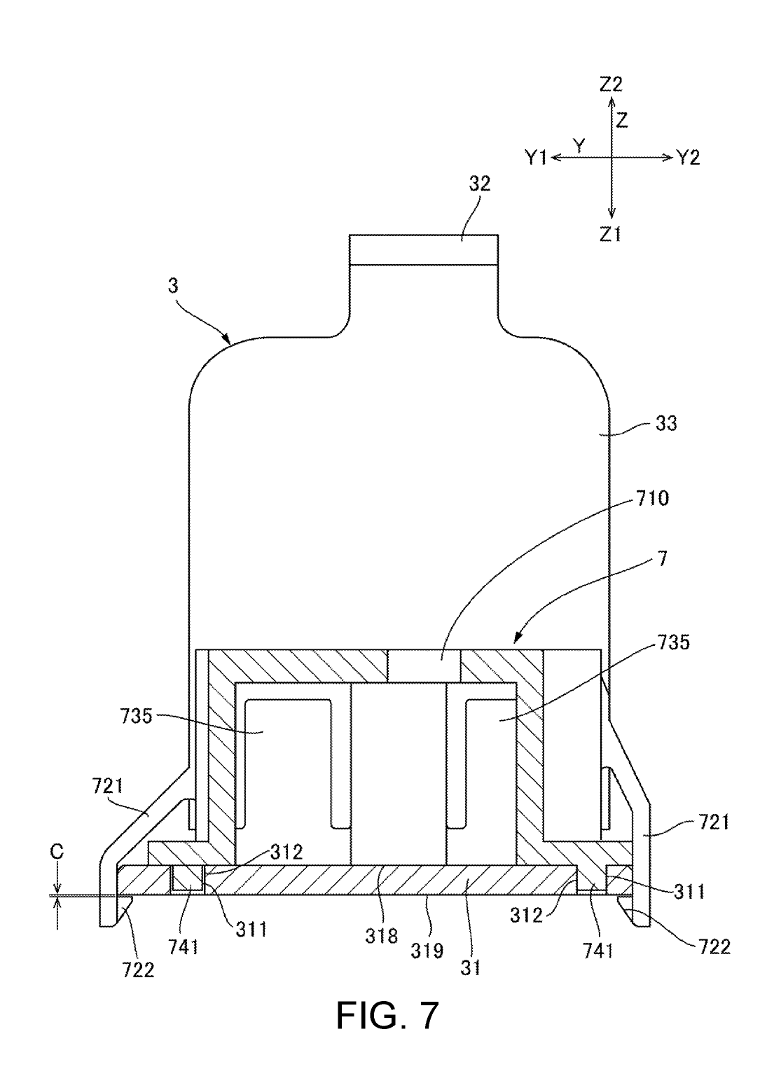

FIG. 5 is an X-Z sectional view illustrating a state where the gear cover 7 and the like are cut at a position passing through a flexible plate 735 of the gear cover 7 in the state illustrated in FIG. 3. FIG. 6 is a cross-sectional view of a state where the gear cover 7 is removed from the state illustrated in FIG. 5. FIG. 7 is a Y-Z sectional view illustrating a state where the gear cover 7 and the like are cut at a position passing through a convex portion 741 of the gear cover 7 in the state illustrated in FIG. 3.

As illustrated in FIG. 3, FIG. 4, FIG. 5, FIG. 6, and FIG. 7, in an approximately center portion in the third direction Y of the third plate 33 of the frame 3, convex portions 331 protruding toward the other side X2 in the first direction X are formed at two positions spaced apart in the Z direction. On the other hand, in an approximately center portion in the third direction Y of the second side plate 73 of the gear cover 7, a groove shaped concave portion 731 extending in the second direction Z is formed at a position overlapping with the two convex portions 331, and the two convex portions 331 are fitted in the concave portion 731.

In the second side plate 73 of the gear cover 7, at both sides of the concave portion 731 in the third direction Y, flexible plates 735 are formed which are obtained by cutting three sides by a groove 732 with an end on the one side Z1 in the second direction Z being intact, and on the other side Z2 in the second direction Z, free ends are formed in the flexible plates 735. Therefore, the other side Z2 of the flexible plates 735 in the second direction Z can be elastically deformed in the first direction X.

On a surface of the flexible plate 735 on the one side X1 in the first direction X, in the vicinity of the end on the other side Z2 in the second direction Z, convex portions 736 protruding toward the one side X1 in the first direction X are formed. The end of the convex portion 736 on the other side Z2 in the second direction Z is an inclined surface 737 inclined toward both the one side X1 in the first direction X and the other side Z2 in the second direction Z. It is noted that the end of the convex portions 736 on the one side Z1 in the second direction Z is also an inclined surface 738. On the other hand, at a position overlapping with each of the two convex portions 736 in the third plate 33 of the frame 3, quadrilateral opening portions 336 are formed, and the convex portions 736 are each fitted in the two opening portions 336. The two opening portions 336 are inclined surfaces 337 in which an opening edge on the other side X2 in the first direction X is inclined toward both the other side X2 in the first direction X and the one side Z1 in the second direction Z.

Each of the two flanges 74 of the gear cover 7 is formed with a round bar shaped convex portion 741 protruding toward the one side Z1 in the second direction Z. On the other hand, in the first plate 31 of the frame 3, a circular hole 311 is formed at a position overlapping with each of the two convex portions 741, and the convex portions 741 are fitted in each of the two holes 311.

Hooks 721 are formed which protrude obliquely toward the one side Z1 in the second direction Z from the outer surface of each of portions facing in the third direction Y in the first side plate 72 of the gear cover 7, and further extend toward the one side Z1 in the second direction Z. At ends of the two hooks 721 on the one side Z1 in the second direction Z, claws 722 overlapping with a surface 319 of the first plate 31 on the one side Z1 in the second direction Z are formed and the claws 722 are engaged with the first plate 31.

### Manufacturing Method of Motor 1

Again, in FIG. 1 and FIG. 2, when the motor 1 according to the present embodiment is manufactured, the frame 3 is fixed to the motor main body 10, and then, the motor pinion 55 is attached to the motor shaft 50. Next, the rotation shaft 8 is inserted from the other side X2 in the first direction X toward a space between the first plate 31 and the second plate 32 of the frame 3. In the present embodiment, the rotation shaft 8 is passed through the through hole 710 of the gear cover 7, the rotation shaft 8 and the gear cover 7 are inserted together from the other side X2 in the first direction X toward the space between the first plate 31 and the second plate 32 to fix the gear cover 7 to the frame 3.

Next, after the fixation shaft 35 is inserted into the shaft hole 81 of the rotation shaft 8 from the through hole 37 of the second plate 32, the fixation shaft 35 is fixed. As a result, the rotation shaft 8 is rotatably supported by the fixation shaft 35. At that time, the gear 85 of the rotation shaft 8 and the motor pinion 55 are meshed.

### Fixing Structure of Gear Cover 7 to Frame 3

In the present embodiment, the gear cover 7 is fixed to the frame 3. Therefore, if the gear cover 7 is mentioned as a claimed “cover”, the frame 3 corresponds to a claimed “supporting member”. In the present embodiment, when the gear cover 7 is fixed to the frame 3, the gear cover 7 is pressed against the third plate 33 and the gear cover 7 is also pressed against the first plate 31. As a result, as illustrated in FIG. 1, FIG. 3, FIG. 5, and FIG. 7, the convex portion 736 of the flexible plate 735 of the gear cover 7 fits inside the opening portion 336 of the third plate 33, the convex portion 331 of the third plate 33 fits into the concave portion 731 of the gear cover 7, and the convex portion 741 of the gear cover 7 fits into the hole 311, and as a result, the hook 721 of the gear cover 7 engages with the first plate 31.

At that time, as described below, the third plate 33 of the frame 3 acts as a claimed “first support unit” and the first plate 31 acts as a claimed “second support unit”. Further, the flexible plate 735 of the gear cover 7 and the opening portion 336 of the third plate 33 function as a claimed “biasing force generation unit” configured to generate a biasing force for biasing the gear cover 7 in an inclined direction inclined toward both the other side X2 in the first direction X and the one side Z1 in the second direction Z. Further, the surface 318 facing the other side Z2 in the second direction Z of the first plate 31 functions as a claimed “first abutment unit” configured to abut against the gear cover 7 from the one side Z1 in the second direction Z, and out of the inner peripheral surface 312 of the hole 311 formed in the first plate 31, a portion positioned on the other side X2 in the first direction X functions as a claimed “second abutment unit” configured to abut against the gear cover 7 from the other side X2 in the first direction X.

More specifically, in a state illustrated in FIG. 1, FIG. 3, FIG. 5, and FIG. 7, the inclined surface 737 of the convex portion 736 formed in the flexible plate 735 of the gear cover 7 acts as a contact surface between the gear cover 7 and the third plate 33, and is pressed against the inclined surface 337 of the opening edge of the opening portion 336 of the third plate 33, and as a result, the flexible plate 735 warps toward the other side X2 in the first direction X. Therefore, as indicated by an arrow F in FIG. 5, due to a reaction force obtained when the flexible plate 735 warps, the gear cover 7 receives the biasing force in the inclined direction inclined toward both the other side X2 in the first direction X and the one side Z1 in the second direction Z from the third plate 33. As a result, the surface 318 of the first plate 31 on the other side Z2 in the second direction Z elastically abuts, as the first abutment unit, against the gear cover 7 from the one side Z1 in the second direction Z, and out of the inner peripheral surface 312 of the hole 311 formed in the first plate 31, a portion positioned on the other side X2 in the first direction X elastically abuts, as the second abutment unit, against the convex portion 741 of the gear cover 7 from the other side X2 in the first direction X.

In this state, the gear cover 7 is fixed to the frame 3, and thus, the hook 721 of the gear cover 7 is engaged with the first plate 31; however, the hook 721 functions to prevent the gear cover 7 from being removed toward the other side Z2 in the second direction Z when a large force is applied to the gear cover 7, and does not directly function to fix the gear cover 7 to the frame 3.

### Main Effect of Present Embodiment

As described above, in the motor 1 of the present embodiment, upon fixing the gear cover 7 (cover) to the frame 3 (support member), the frame 3 includes the third plate 33 (first support unit) configured to support the gear cover 7 on the one side X1 in the first direction X, and the first plate 31 (second support unit) configured to support the gear cover 7 on the one side Z1 in the second direction Z. Further, the gear cover 7 includes the flexible plate 735 (biasing force generation unit) configured to generate the biasing force for biasing the gear cover 7 in the inclined direction inclined toward both the other side X2 in the first direction X and the one side Z1 in the second direction Z, upon pressing the gear cover 7 against the third plate 33. On the other hand, the first plate 31 includes the surface 318 (first abutment unit) configured to elastically abut against the gear cover 7 from the one side Z1 in the second direction Z, and the hole 311 including the inner peripheral surface 312 (second abutment unit) configured to elastically abut against the convex portion 741 of the gear cover 7 from the other side X2 in the first direction X. Therefore, the gear cover 7 can be fixed to the third plate 33 and the first plate 31 by a simple operation of pressing the gear cover 7 toward the third plate 33 of the frame 3. Further, since the gear cover 7 is elastically fixed to the third plate 33 and the first plate 31, rattling hardly occurs.

In addition, the flexible plate 735 is formed with the inclined surface 737 formed to face an inclined direction inclined toward both the one side X1 in the first direction X and the other side X2 in the second direction Z. Therefore, since the biasing force generation unit can be configured by the flexible plate 735 provided in the gear cover 7 itself, it is unnecessary to add another member to configure the biasing force generation unit.

Further, the inclined surface 737 is formed in the convex portion 736 protruding from the flexible plate 735 toward the one side X1 in the first direction X, and abuts against the opening edge (inclined surface 737) of the opening portion 336 opening toward the other side X2 in the first direction X in the third plate 33. Therefore, when the gear cover 7 is pressed against the third plate 33, the biasing force for biasing the gear cover 7 in the inclined direction inclined toward both the other side X2 in the first direction X and the one side Z1 in the second direction Z can be reliably generated, and generation of a large gap between the third plate 33 and the gear cover 7 can be avoided.

Further, since the second abutment unit is the inner peripheral surface 312 of the hole 311 formed in the first plate 31 so that the convex portion 741 formed in the gear cover 7 fits, the second abutment unit can be formed with a simple configuration.

In addition, since the hook 721 elastically engaging with the first plate 31 is formed in the gear cover 7, even if a large force is applied to the gear cover 7, it is possible to prevent the gear cover 7 from coming off to the other side Z2 in the second direction Z, and further, since the gear cover 7 is fixed by the flexible plate 735, the first plate 31 (first abutment unit), and the hole 311, even if a clearance C (see FIG. 7) between the hook 721 and the first plate 31 is large, rattling hardly occurs. Therefore, since a large force is not required for the engagement of the hook 721, the assembly work can be performed efficiently.

Since the engagement unit configured to position the gear cover 7 in the third direction Y is configured of the convex portion 331 formed in the third plate 33 and the concave portion 731 formed in the gear cover 7, the gear cover 7 can be surely positioned in the third direction Y. In addition, since the two convex portions 331 formed in the third plate 33 are fitted in the groove shaped concave portion 731 formed in the gear cover 7, the inclination of the gear cover 7 can be suppressed.

### Other Embodiments

In the above embodiment, the flexible plate 735 (biasing force generation unit) is formed on the side of the gear cover 7, but the flexible plate 735 may be formed on the side of the third plate 33 of the frame 3. In the above embodiment, the second abutment unit is configured by the inner peripheral surface of the hole 311 formed as a through hole, but it is also possible to adopt a mode in which the hole 311 is a bottomed concave portion. In the above embodiment, the convex portion 741 is formed on the side of the gear cover 7, but the convex portion 741 may be formed on the side of the first plate 31 of the frame 3, and a through hole or the bottomed hole 311 may be formed on the side of the gear cover 7. In this case, the second abutment unit is configured by the outer peripheral surface of the convex portion 741. In the above embodiment, the convex portion 331 is formed on the side of the first plate 31 of the frame 3, but the convex portion 331 may be formed on the side of the gear cover 7 and the concave portion 731 may be formed on the side of the first plate 31 of the frame 3.

In the above embodiment, the structure for fixing the gear cover 7 to the frame 3 is mainly described, but the present invention may also be applied to a case where the cover is fixed to another support member.

### DESCRIPTION OF THE REFERENCE NUMERALS

1: Motor
3: Frame (support member)
7: Gear cover (cover)
8: Rotation shaft
9: Gear transmission mechanism
10: Motor main body
311: Hole
31: First plate (second support unit)
32: Second plate
33: Third plate (first support unit)
35: Fixation shaft
50: Motor shaft
55: Motor pinion
71: End plate
72: First side plate
73: Second side plate
74: Flange
311: Hole
312: Inner peripheral surface (second abutment unit)
318: Surface (first abutment unit)
331, 736, 741: Convex portion
336: Opening portion
337, 737: Inclined surface
721: Hook
722: Claw
731: Concave portion
735: Flexible plate (biasing force generation unit)
C: Clearance
L: Motor axis
L1: Output side
L2: Opposite output sideX: First direction
Y: Third direction
Z: Second direction
X1: One side in first direction
X2: Other side in first direction
Z1: One side in second direction
Z2: Other side in second direction

1. A cover fixing structure for fixing a cover to a support member, wherein
the support member comprises a first support unit configured to support the cover on one side in a first direction, and a second support unit configured to support the cover at one side in a second direction orthogonal to the first direction,
one of the cover and the support member comprises a biasing force generation unit configured to generate, in a case that the cover is pressed against the first support unit, a biasing force for biasing the cover in an inclined direction inclined toward both an other side in the first direction and the one side in the second direction, and
the second support unit comprises a first abutment unit configured to abut the cover from the one side in the second direction, and a second abutment unit configured to abut the cover from the other side in the first direction.

2. The cover fixing structure according to claim 1, wherein the biasing force generation unit is a flexible plate configured to warp while an inclined surface inclined toward both the first direction and the second direction being a contact surface between the cover and the first support unit in a case that the cover is pressed against the first support unit, to generate the biasing force.

3. The cover fixing structure according to claim 2, wherein the flexible plate is formed in the cover to extend in the second direction with a free end thereof facing an other side in the second direction,
the flexible plate is formed with the inclined surface formed to face an inclined direction inclined toward both the one side in the first direction and the other side in the second direction, and
the flexible plate warps toward the other side in the first direction in a case that the cover is pressed against the first support unit, to generate the biasing force.

4. The cover fixing structure according to claim 3, wherein the inclined surface is formed in a convex portion protruding from the flexible plate toward the one side in the first direction, and
the first support unit is provided with an opening portion opening toward the other side in the first direction, the convex portion fitting into the opening portion in a case that the cover is pressed against the first support unit, and an opening edge on the other side in the first direction of the opening portion abuts the inclined surface.

5. The cover fixing structure according to claim 1, wherein the second abutment unit is formed of an inner peripheral surface of a hole into which a convex portion formed on the cover is fitted, the hole being provided in the second support unit, and an outer peripheral surface of a convex portion to be fitted into the hole formed on the cover, the convex portion being formed in the second support unit.

6. The cover fixing structure according to claim 1, wherein the cover comprises a hook protruding toward an other side in the second direction and elastically engaging with the second support unit.

7. The cover fixing structure according to claim 1, wherein an engagement unit configured to position a third direction orthogonal to both the first direction and the second direction of the cover is configured of a convex portion formed in one of the first support unit and the cover and a concave portion formed in the other one of the first support unit and the cover, where the convex portion is fitted into the concave portion.

8. A motor comprising:
a cover fixing structure for fixing a cover to a support member;
wherein the support member comprises a first support unit configured to support the cover on one side in a first direction, and a second support unit configured to support the cover at one side in a second direction orthogonal to the first direction;
wherein one of the cover and the support member comprises a biasing force generation unit configured to generate, in a case that the cover is pressed against the first support unit, a biasing force for biasing the cover in an inclined direction inclined toward both an other side in the first direction and the one side in the second direction; and
the second support unit comprises a first abutment unit configured to abut the cover from the one side in the second direction, and a second abutment unit configured to abut the cover from the other side in the first direction;
a motor main body comprising a motor axis extending along the second direction;
a frame comprising a first plate fixed to an end on an other side in the second direction of the motor main body, a second plate facing the first plate on the other side in the second direction, and a third plate configured to couple the first plate and the second plate at one side in the first direction;
a rotation shaft arranged between the first plate and the second plate;
a gear transmission mechanism configured to transmit rotation of a motor shaft of the motor main body to a gear unit of the rotation shaft; and
a gear cover fixed to the frame to cover the gear transmission mechanism between the first plate and the second plate,
wherein
the frame is the support member,
the gear cover is the cover,
the third plate is the first support unit, and
the first plate is the second support unit.

9. The motor according to claim 8, wherein the biasing force generation unit is a flexible plate configured to warp while an inclined surface inclined toward both the first direction and the second direction being a contact surface between the cover and the first support unit in a case that the cover is pressed against the first support unit, to generate the biasing force.

10. The motor according to claim 9, wherein the flexible plate is formed in the cover to extend in the second direction with a free end thereof facing an other side in the second direction,
the flexible plate is formed with the inclined surface formed to face an inclined direction inclined toward both the one side in the first direction and the other side in the second direction, and
the flexible plate warps toward the other side in the first direction in a case that the cover is pressed against the first support unit, to generate the biasing force.

11. The motor according to claim 10, wherein the inclined surface is formed in a convex portion protruding from the flexible plate toward the one side in the first direction, and
the first support unit is provided with an opening portion opening toward the other side in the first direction, the convex portion fitting into the opening portion in a case that the cover is pressed against the first support unit, and an opening edge on the other side in the first direction of the opening portion abuts the inclined surface.

12. The motor according to claim 8, wherein the second abutment unit is formed of an inner peripheral surface of a hole into which a convex portion formed on the cover is fitted, the hole being provided in the second support unit, and an outer peripheral surface of a convex portion to be fitted into the hole formed on the cover, the convex portion being formed in the second support unit.

13. The motor according to claim 8, wherein the cover comprises a hook protruding toward an other side in the second direction and elastically engaging with the second support unit.

14. The motor according to claim 8, wherein an engagement unit configured to position a third direction orthogonal to both the first direction and the second direction of the cover is configured of a convex portion formed in one of the first support unit and the cover and a concave portion formed in the other one of the first support unit and the cover, where the convex portion is fitted into the concave portion.
